(19) United States
(12) Patent Application Publication
(10) Pub. No.: US 2006/0083997 A1
(43) Pub. Date: Apr. 20, 2006

(54) Photomask with wavelength reduction material and pellicle

(75) Inventors: Burn Jeng Lin, Hsin-Chu (TW); Jeng-Horng Chen, Hsin-Chu (TW); Chun-Kuang Chen, Hsin-Chu (TW); Tsai-Sheng Gau, Hsinchu City (TW); Ru-Gun Liu, Hsinchu City (TW); Jen-Chieh Shih, Jhubei City (TW); Hua-Tai Lin, HsinChu (TW); Hung Chiang Hsieh, Hsin-Chu City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/248,070

(22) Filed: Oct. 12, 2005

Related U.S. Application Data
(63) Continuation-in-part of application No. 10/964,842, filed on Oct. 13, 2004.
(60) Provisional application No. 60/511,503, filed on Oct. 15, 2003.

(51) Int. Cl. A47G 1/12; G03F 1/14; G03F 1/00

(52) U.S. Cl. 430/5; 428/14

(57) ABSTRACT

Disclosed is a photomask comprising a transparent substrate, an absorption layer proximate to the transparent substrate, and a pellicle mounted proximate to the transparent substrate. The absorption layer has at least one opening formed therein for receiving a wavelength-reducing material (WRM). The wavelength-reducing material and the absorption layer form a generally planar surface.

### RELATED APPLICATIONS

This application is a continuation-in-part of U.S. Utility Patent Application Serial No. 10/964,842, filed on Oct. 13, 2004 and entitled “A Device and Method for Providing Wavelength Reduction with a Photomask”, which claims priority to U.S. Provisional Patent Application Ser. No. 60/511,503, filed on Oct. 15, 2003 and entitled the same.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing have been needed.

For example, in the course of integrated circuit evolution, functional density (i.e., the number of interconnected devices per chip area) has generally increased while feature size (i.e., the smallest component or line that can be created using a fabrication process) has decreased. This scaling down process generally provides benefits by increasing production efficiency and lowering associated costs, but needs to be matched by improvements in the fabrication process. For instance, many fabrication processes utilize a photomask to form a pattern during photolithography. The pattern may contain a pattern of designed circuits that will be transferred onto a semiconductor wafer. However, because of the increasingly small patterns that are to be used during photolithography, photomasks have generally needed increasingly high resolutions.

### SUMMARY

In one embodiment, the present disclosure provides a photomask for forming a pattern during photolithography when illuminated with a predetermined wavelength of light. The photomask comprises a transparent substrate; an absorption layer proximate to the substrate, wherein the absorption layer has at least one opening formed therein; and a layer of wavelength-reducing material disposed in at least one opening, wherein a thickness of the wavelength-reducing material and the absorption layer form a generally planar surface.

### BRIEF DESCRIPTION OF THE DRAWINGS

FIG. 1 illustrates a cross-sectional view of one embodiment of a photomask with a wavelength reducing medium.

FIG. 2 is a flow chart of an exemplary method for forming the photomask of FIG. 1.

FIGS. 3a-3c illustrate various fabrication stages of the photomask of FIG. 1 as it is formed using the method of FIG. 2.

FIG. 4 illustrates a cross-sectional view of another embodiment of a photomask with a wavelength reducing medium.

FIG. 5 is a flow chart of an exemplary method for forming the photomask of FIG. 4.

FIGS. 6a-6c illustrate various fabrication stages of the photomask of FIG. 4 as it is formed using the method of FIG. 5.

FIG. 7 illustrates a cross-sectional view of yet another embodiment of a photomask with a wavelength reducing medium.

FIG. 8 is a flow chart of an exemplary method for forming the photomask of FIG. 7.

FIGS. 9a-9c illustrate various fabrication stages of the photomask of FIG. 7 as it is formed using the method of FIG. 8.

FIGS. 10a and 10b illustrate a top view and a cross-sectional view, respectively, of an embodiment of a photomask with a wavelength reducing medium and pellicle.

FIGS. 11a and 11b illustrate a top view and a cross-sectional view , respectively, of another embodiment of a photomask with a wavelength reducing medium and pellicle.

FIGS. 12a and 12b illustrate a top view and a cross-sectional view, respectively, of an embodiment of a photomask during a manufacturing stage.

FIGS. 13a and 13b illustrate a top view and a cross-sectional view, respectively, of an embodiment of a photomask during a manufacturing stage.

FIGS. 14, 15, 16, 17, 18, 19a, 19b, and 20 illustrate schematic views of various embodiments of a photomask during manufacturing stages.

### DETAILED DESCRIPTION

The present disclosure relates generally to photolithography and, more particularly, to using a wave-length reducing medium with a photomask. It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

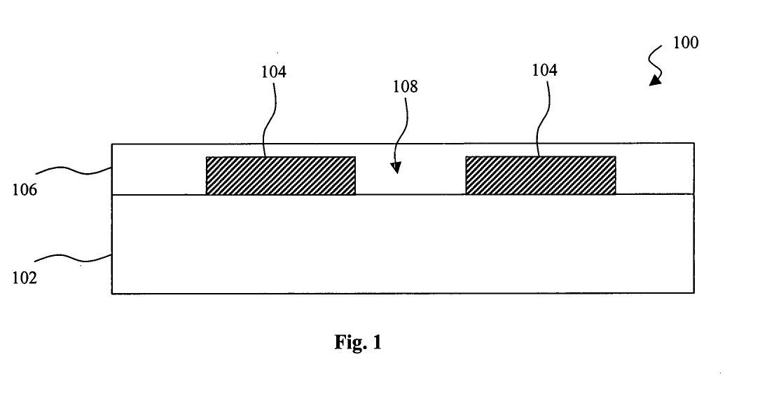

Referring to FIG. 1, a cross-sectional view of one embodiment of a photomask 100 is illustrated. The photomask 100 comprises a transparent substrate 102, an absorption layer 104, and a wavelength-reducing material (WRM) 106. The transparent substrate 102 may use fused silica (SiO2) or a glass relatively free of defects, such as borosilicate glass and soda-lime glass. Other suitable materials may also be used.

The absorption layer 104 may be formed using a number of different processes and materials, such as depositing of a metal film made with Chromium (Cr) and iron oxide, or an inorganic film made with MoSi, ZrSiO, and SiN. The absorption layer 104 may be patterned to have one or more openings 108 through which light may travel without being absorbed by the absorption layer. In some embodiments, the absorption layer 104 may have a multi-layer structure, which may further include an antireflection (ARC) layer and/or other layers. In addition, some of these layers may be formed multiple times to achieve a desired composition of the absorption layer 104.

The absorption layer 104 may be tuned to achieve a predetermined transmittance and an amount of phase shifting, enabling the absorption layer 104 to shift the phase of light passing through the absorption layer, for improved imaging resolution. For example, the transmittance of the absorption layer 104 may be tuned to between approximately three percent and thirty percent, while the phase shift is tuned to approximately 180 degrees. This type of photomask is sometimes referred to as an attenuated phase-shifting photomask. In another example, the transmittance of the absorption layer 104 may be extremely high (e.g., 95%), and the phase shift may be approximately 180 degrees. This type of photomask is sometimes referred to as a chromeless phase-shifting photomask.

The WRM 106 may be used to fill in the one or more openings 108 of the absorption layer 104. The surface of the WRM 106 may be substantially co-planar with the surface of the absorption layer 104, but may be fine tuned to be slightly higher or lower with the plane of the surface of the absorption layer 104. Both materials may be planarized using known planarization techniques, such as chemical-mechanical planarization (CMP) to form a planar surface. The thickness of the WRM 106 may vary from less than to about the thickness of the absorption layer 104 (e.g., if the surface of the WRM is aligned with the surface of the absorber), to up to about ten times the wavelength of light passing through the WRM 106 during photolithographic processing. The WRM material used for the WRM 106 may be chosen based on a desired level of transparency and a desired refractive index. The WRM 106 preferably has a refractive index different from that of the absorption layer. In the present example, the WRM material is selected to provide both a high level of transparency and a high refractive index. Exemplary WRM materials include photoresist materials, polymer materials, and dielectric materials. For example, the material may include polyimide, SiO2, indium tin oxide (ITO), polyvinyl alcohol (PVA), or silicone.

During a photolithography process, the photomask 100 is disposed above a semiconductor formation. Typically, the photomask 100 does not come into contact with the surface of the semiconductor formation. Due to the relatively high refractive index (“n”) of the WRM 106, the wavelength of the light passing through the WRM 106 during photolithography processing may be reduced by a factor of n from the wavelength of the light in a vacuum. Since the physical size of the opening 108 in the absorption layer 104 remains the same, but the size of the opening 108 relative to the wavelength of the light is enlarged by the factor of n, optical diffraction is reduced accordingly and the resolution of imaging of the photomask 100 on a wafer may be enhanced.

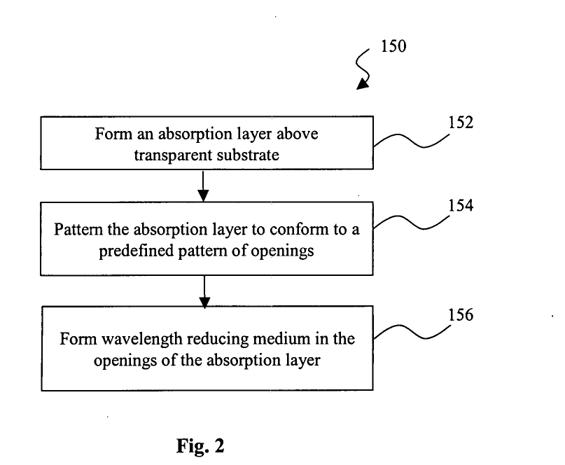

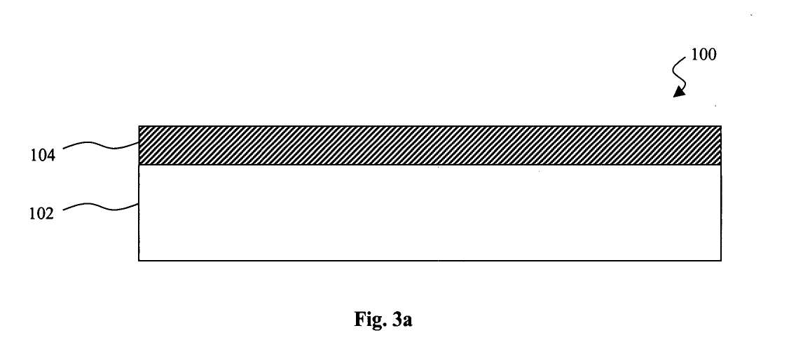

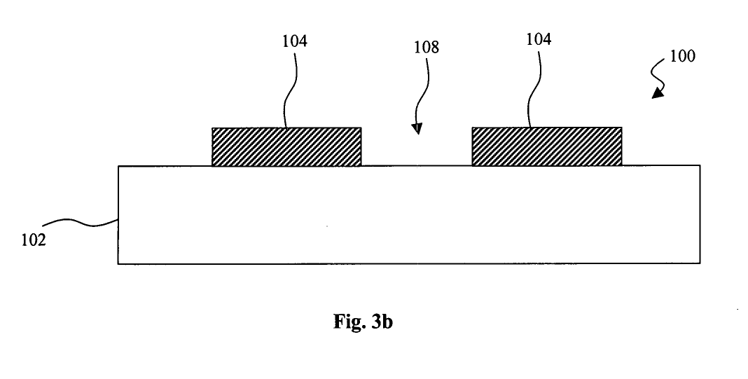

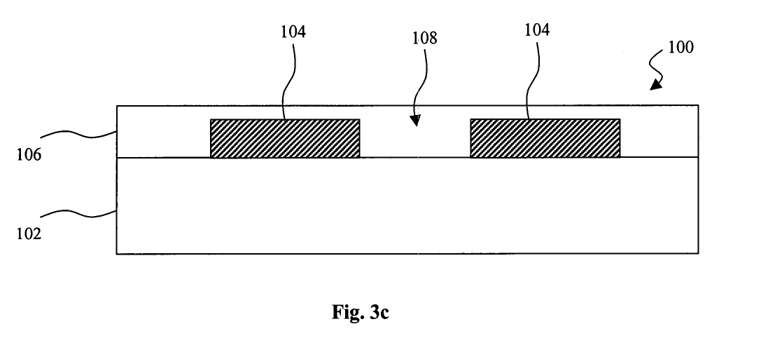

Referring now to FIG. 2 and with additional reference to FIGS. 3a-3c, an exemplary method 150 may be used to form the photomask 100 of FIG. 1. The method 150 begins in step 152 with the formation of the absorption layer 104 above the transparent substrate 102 as shown in FIG. 3a. It is understood that the transparent substrate 102 may be cleaned or otherwise prepared using processes not illustrated in the present example of method 100. The absorption layer 104 may be formed using a process such as a physical vapor deposition (PVD) process, including evaporation and sputtering, a plating process, including electroless plating or electroplating, or a chemical vapor deposition (CVD) process, including atmospheric pressure CVD (APCVD), low pressure CVD (LPCVD), plasma enhanced CVD (PECVD), or high density plasma CVD (HDP CVD). In the present example, a sputtering deposition may be used to provide the absorption layer 104 with thickness uniformity, relatively few defects, and a desired level of adhesion. As previously described with respect to FIG. 1, the absorption layer 104 may include materials such as Chromium, iron oxide, MoSi, ZrSiO, and SiN.

In step 154 (FIG. 3b), the absorption layer 104 may be patterned to have a predefined arrangement of openings 108 using known processes such as a photolithography process or an electron beam process. For example, the photolithography process may include the following processing steps. A photoresist layer (not shown) may undergo a process involving spin-on coating, baking, exposure to illuminated light through a photomask, developing, and post baking. This transfers the pattern from the photomask to the photoresist. Next, a wet etching or dry etching may be used to etch an exposed region of the absorption layer 104 to transfer the pattern from the photoresist to the absorption layer. The photoresist may then be stripped by wet stripping or plasma ashing. In the present example, the patterned absorption layer has at least one opening, as shown in FIG. 3b.

In step 156 and with additional reference to FIG. 3c, the WRM 106 may be formed in the opening of the absorption layer 104 using a process such as a spin-on coating, CVD, atomic layer deposition, or PVD. Depending on a desired thickness of the WRM or upon a desired height of the WRM relative to the surface of the absorption layer 104, the surface of the WRM is substantially co-planar with the absorption layer, but may be fine-tuned to be slightly higher or lower than the surface of the absorption layer 104. A planarizing process, such as CMP may be used to planarize the WRM 106 and the absorption layer 104. In the present example, the thickness of the WRM ranges from about the thickness of the absorption layer 104 to approximately ten times the wavelength of light passing through the WRM during photolithography processing. The WRM may use a material of high transparency and high refractive index, including photoresist materials, polymer materials, and dielectric materials. Examples of WRM materials include polyimide, SiO2, ITO, PVA, and silicone.

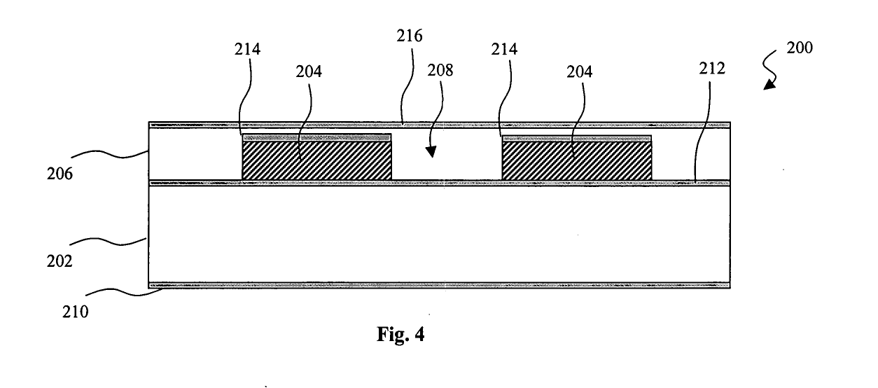

Referring now to FIG. 4, a cross-sectional view of another embodiment of a photomask 200 is illustrated. The photomask 200 comprises a transparent substrate 202, an absorption layer 204, a WRM 206, and a plurality of antireflection coating (ARC) layers. As the transparent substrate 202, absorption layer 204, and WRM 206 are similar to those described with respect to FIG. 1, they will not be described in detail in the present example.

For purposes of illustration, the ARC layers may include an ARC layer 210 on an underside (relative to the absorption layer 204) of the substrate 202, an ARC layer 212 between the substrate 202 and the absorption layer 204, an ARC layer 214 between the absorption layer 204 and the WRM 206, and/or an ARC layer 216 above the WRM 206. It is understood that the ARC layer 214 may not cover the sidewall of the patterned absorption layer 204, depending on a particular processing sequence or processing method used to form the photomask 100.

The ARC layers 210, 212, 214, 216 may be used at an interface to reduce stray light introduced by the photomask. Such interfaces may include an interface between the substrate 202 and the absorption layer 204 (using the ARC layer 212), an interface between the absorption layer 204 and the WRM 206 (using the ARC layer 214), and an interface between the substrate 202 and the WRM 206 (using the ARC layer 212), even though these ARC layers may function differently. For example, the ARC layer 214 on the absorption layer 204 may eliminate stray light contributed by the high reflectivity of the absorption layer. The ARC layer 216 on the WRM 206 may reduce multiple reflections between the outer face of the WRM 206 and the absorption layer 204. It may also reduce the reflection between the WRM 206 and the space outside. The ARC layer 212 on the substrate may reduce flare back into an illumination system used during photolithography and may provide a smooth transition between the substrate 202 and the WRM 206 to eliminate mismatch of the refractive index.

Each ARC layer may have multi-level structure that provides each ARC layer with multiple layers having different refractive indices. For example, the ARC layers may have a graded structure where the refractive index of each ARC layer changes gradually to match the refractive indexes of neighboring materials in the photomask 100. The ARC layers may comprise an organic material containing hydrogen, carbon, or oxygen; compound materials such as Cr2O3, ITO, SiO2, SiN, TaO5, Al2O3, TiN, and ZrO; metal materials such as Al, Ag, Au, and In; or combination thereof.

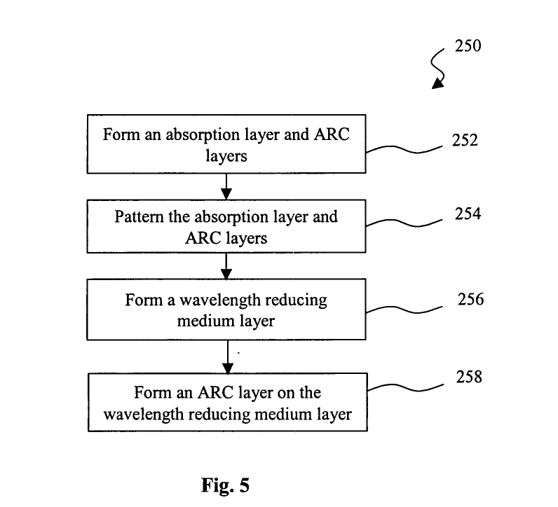

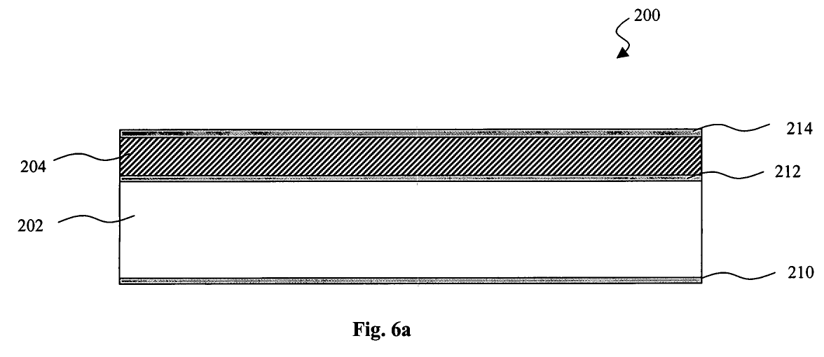

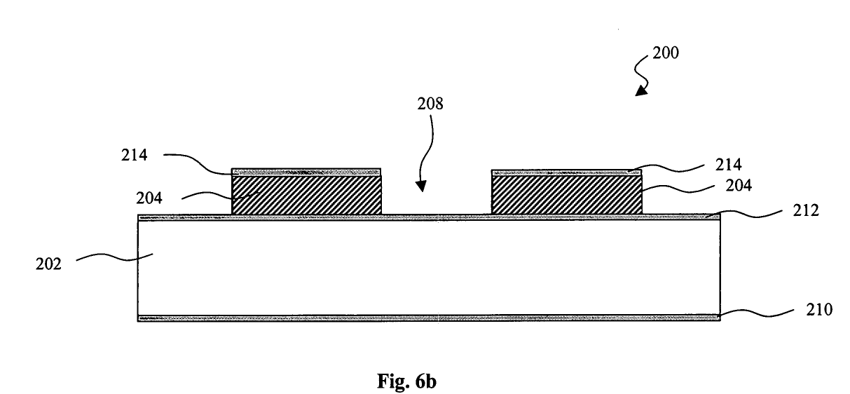

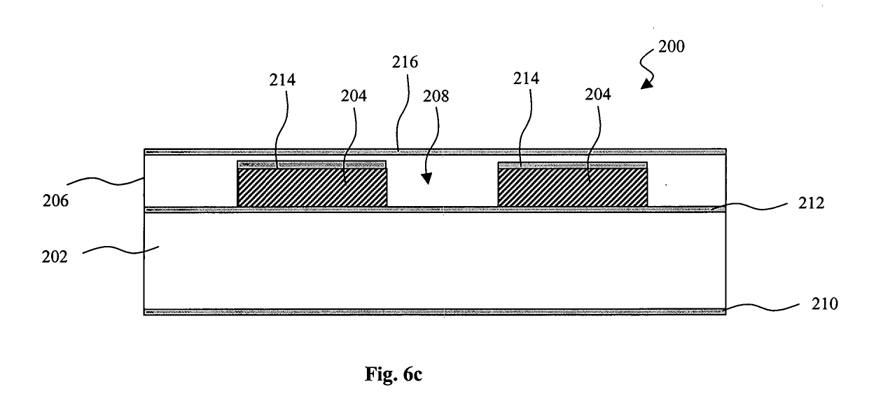

Referring now to FIG. 5 and with additional reference to FIGS. 6a-6c, an exemplary method 250 may be used to form the photomask 200 of FIG. 4. The method 250 begins in step 252 with the formation of the ARC layer 210 on the substrate 202, the formation of the ARC layer 212 on the other side of the substrate 202, the formation of the absorption layer 204, and the formation of the ARC layer 214 above the absorption layer 204.

As previously described, materials used for the absorption layer 204 may include metal film such as Chromium (Cr) and iron oxide, or inorganic films such as MoSi, ZrSiO, and SiN. The absorption layer 204 may be formed using CVD, plating, or PVD processes. In the present example, sputtering deposition may be preferred to provide the absorption layer 204 with thickness uniformity, relatively few defects, and better adhesion.

The ARC layers may use an organic material containing hydrogen, carbon, or oxygen; compound materials including Cr2O3, ITO, SiO2, SiN, TaO5, Al2O3, TiN, and ZrO; metal materials such as Al, Ag, Au, and In; or combination thereof. Methods used to form the ARC layers include spin-on coating, CVD, plating, or PVD.

In step 254, the absorption layer 204 and the ARC layer 214 may be patterned to have a predefined arrangement of openings as previously described with respect to the method 150 of FIG. 2. The ARC layer 214 may be patterned using a processing sequence similar to that used for the absorption layer 204, but may use a different etchant. It is noted that the ARC layer 214 does not cover the sidewalls of the absorption layer 204 (e.g., the walls of the openings 208). In step 256, the WRM 206 may be formed and, in step 258, the ARC layer 216 may be formed using similar materials and processing methods as those used in step 252.

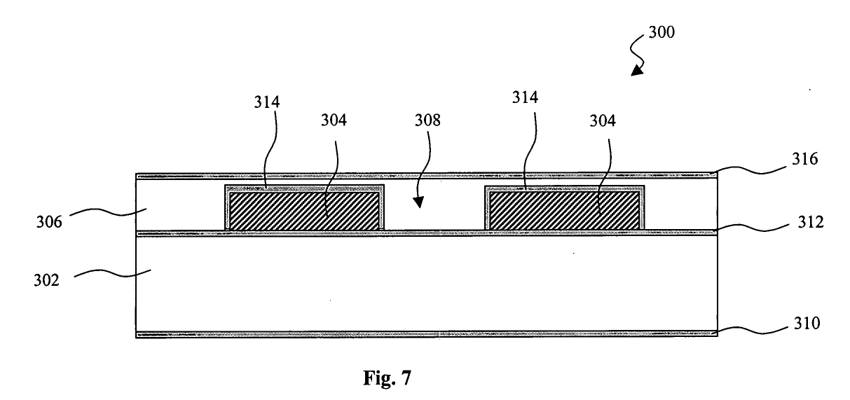

Referring now to FIG. 7, a cross-sectional view of yet another embodiment of a photomask 300 is illustrated. The photomask 300 comprises a transparent substrate 302, an absorption layer 304, a WRM 306, and a plurality of antireflection coating (ARC) layers. As the transparent substrate 302, absorption layer 304, and WRM 306 are similar to those described previously, they will not be described in detail in the present example.

For purposes of illustration, the ARC layers may include an ARC layer 310 on an underside (relative to the absorption layer 304) of the substrate 302, an ARC layer 312 between the substrate 302 and the absorption layer 304, an ARC layer 314 between the absorption layer 304 and the WRM 306, and/or an ARC layer 316 above the WRM 306. These ARC layers are similar to those described with respect to FIG. 4, except that the ARC layer 214 covers the sidewalls of the absorption layer 304 (e.g., the walls of the openings 308).

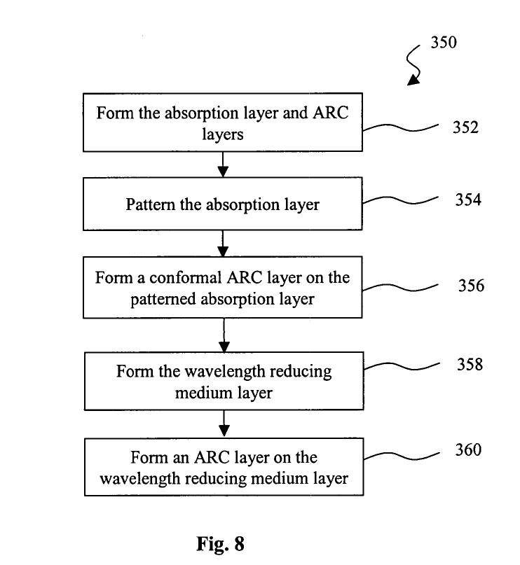

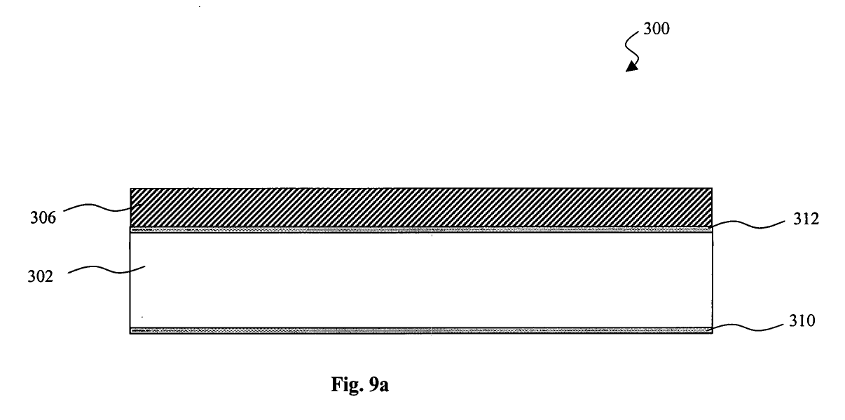

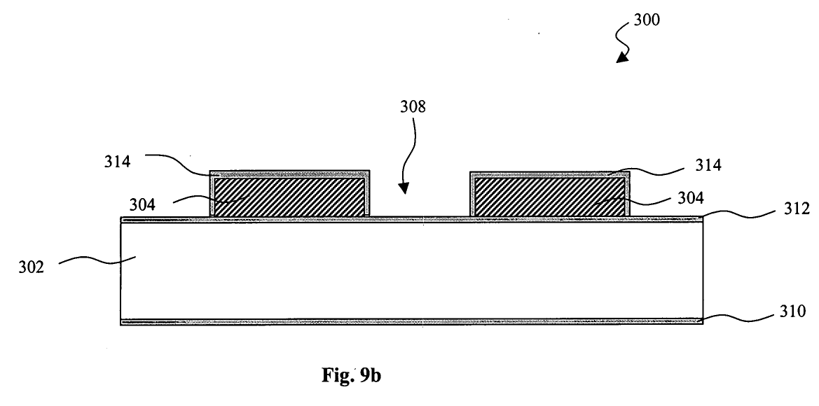

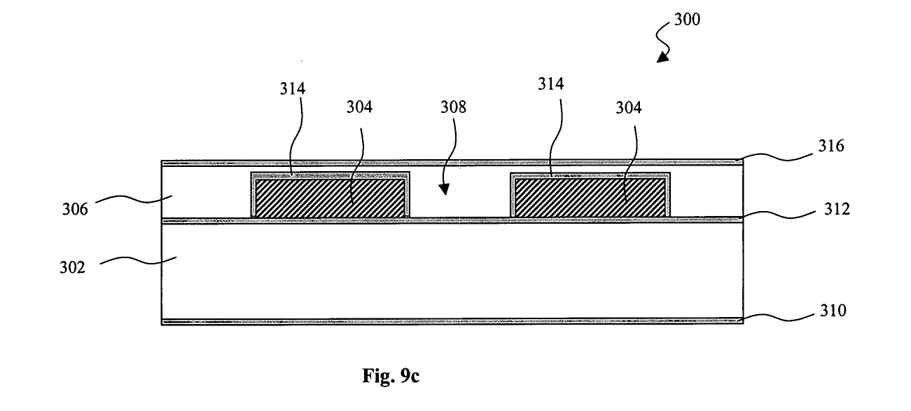

Referring now to FIG. 8 and with additional reference to FIGS. 9a-9c, an exemplary method 350 may be used to form the photomask 300 of FIG. 7. The method 350 begins in step 352 with the formation of the ARC layer 310 on the substrate 302, the formation of the ARC layer 312 on the other side of the substrate 302, and the formation of the absorption layer 304. Unlike the method 250 previously described, the ARC layer 314 is not formed during this step.

In step 354, the absorption layer 304 may be patterned to have a predefined arrangement of openings as previously described and, in step 356, the ARC layer 314 is formed. Since the ARC layer 314 is formed after the absorption layer 304 is formed and patterned, the ARC layer 314 conforms to the shape of the absorption layer 304. This enables the ARC layer 314 to be formed over the sidewalls of the absorption layer 304 (FIG. 8b). In step 358, the WRM 306 may be formed and, in step 360, the ARC layer 316 may be formed using similar materials and processing methods as those used in step 352.

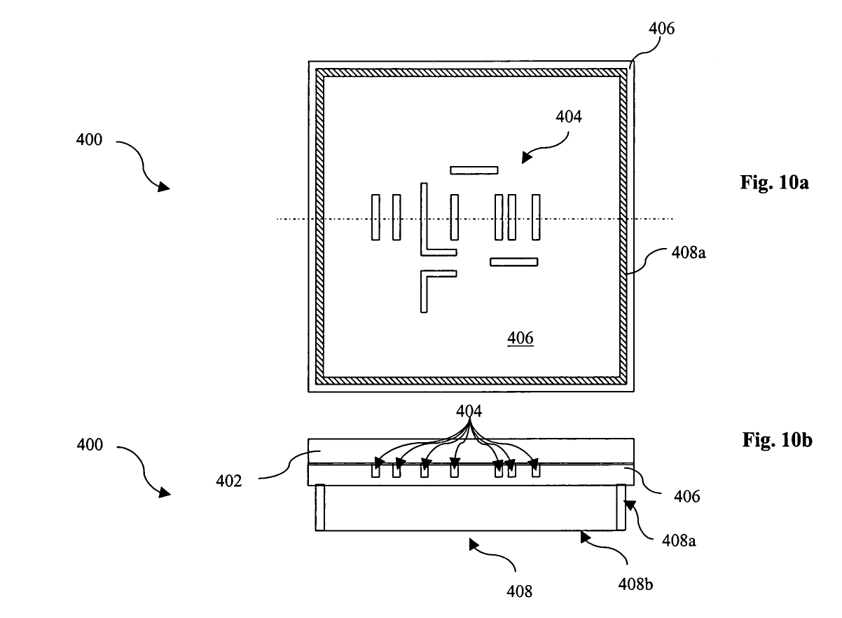

FIGS. 10a and 10b illustrate a top view and a cross-sectional view, respectively, of an embodiment of a photomask having a wavelength-reducing material (WRM) layer and a pellicle. The photomask 400 comprises a transparent substrate 402, an absorption layer 404, and a wavelength-reducing material (WRM) 406. The transparent substrate 402, absorption layer 404, and wavelength-reducing material (WRM) 406 are substantially similar to the transparent substrate 102, absorption layer 104, and wavelength-reducing material (WRM) 106, respectively, in composition, formation, and structure. The photomask 400 may further comprise anti-reflective coating (ARC) layers adjacent the transparent substrate 402, absorption layer 404, and/or wavelength-reducing material (WRM) 406, similar to the photomask 200, or photomask 300 in configuration, composition, and formation. The photomask 400 further comprises a pellicle 408 mounted on the WRM layer. The pellicle 408 may comprise a frame 408a and a film 408b. The frame 408a is attached to the WRM layer 406 at edges thereof by a techniques such as glue for adhesion. The film 408b is configured to have a space from the WRM layer 406 and the absorption layer 402 and substantially covers the both. The pellicle 408 or a second pellicle may be alternatively mounted on the non-patterned side of the transparent substrate.

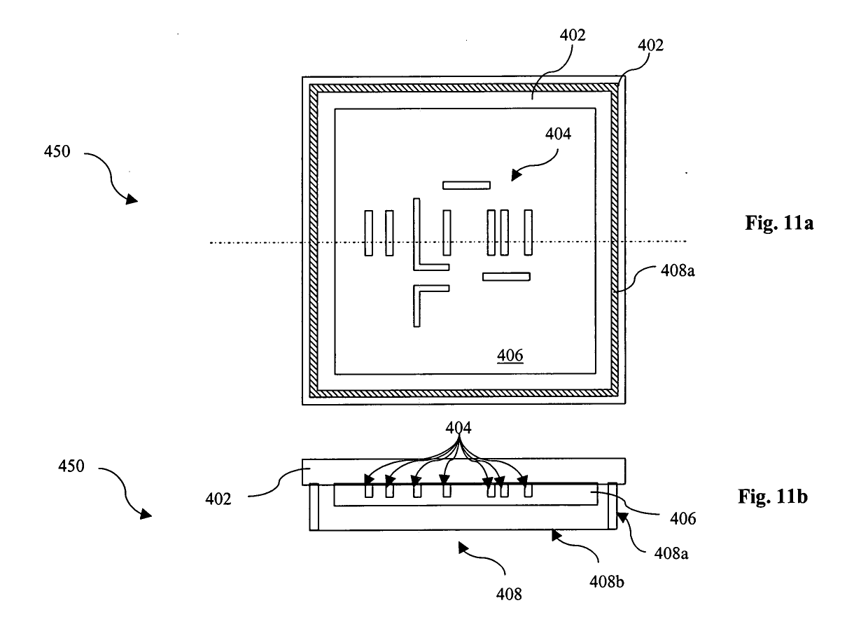

FIGS. 11a and 11b illustrate a top view and a cross-sectional view, respectively, of another embodiment of a photomask having a wavelength-reducing material (WRM) layer and a pellicle. The photomask 450 comprises a transparent substrate 402, an absorption layer 404, and a wavelength-reducing material (WRM) 406 substantially similar to the photomask 400 of FIGS. 10a and 10b in composition, formation, and structure. The photomask 450 may further comprise ARC layers substantially similar to those of the photomask 400 in configuration, composition, and formation. The photomask 450 further comprises a pellicle 408 mounted on the transparent substrate. The pellicle 408 may comprise a frame 408a and a film 408b. The frame 408a is attached to the transparent substrate on the patterned side at edges wherein the edges of the transparent substrate are free of WRM. The frame 408a may be attached thereof by a techniques such as glue. The film 408b is configured to have a space from the WRM layer 406 and the absorption layer 404 and covers the both (404 and 406). The pellicle 408 may be mounted on the other side of the transparent substrate.

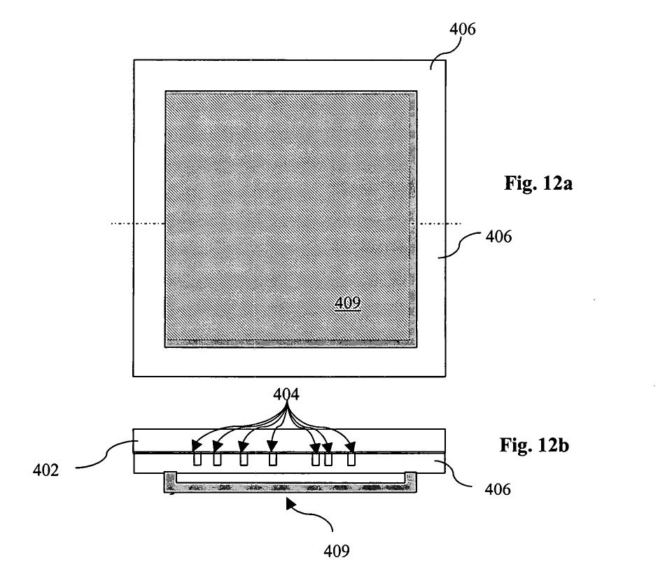

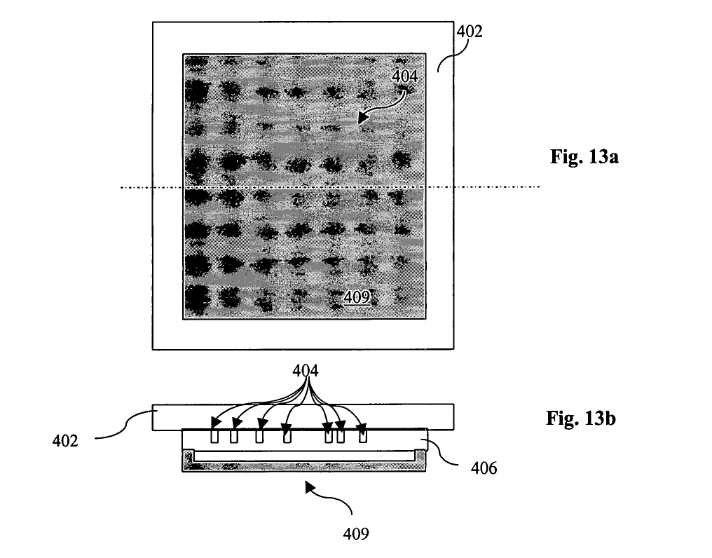

Methods of fabricating the photomask 450 of FIGS. 11a and 11b are described below in various embodiments. Edges of the WRM layer may be removed and then the pellicle is attached to edges of the transparent substrate free of the WRM layer. One method to remove the edges of the WRM layer may utilize a protective cover with reference to FIGS. 12a, 12b, 13a, and 13b.

FIGS. 12a and 12b illustrate a top view and a cross-sectional view, respectively, of a photomask during a manufacturing stage. The absorption layer 404 and the WRM layer 406 are formed on the transparent substrate 402 similar to the method 150. The ARC layers may also be formed thereon similar to the method 250 or the method 350. Then the protective cover 409 is mounted on the WRM layer 406 to cover the absorption layer and substantially covers the WRM layer leaving edges of the WRM layer exposed. The edges have a dimension large enough to hold a pellicle frame but not too large to being over the absorption features 404.

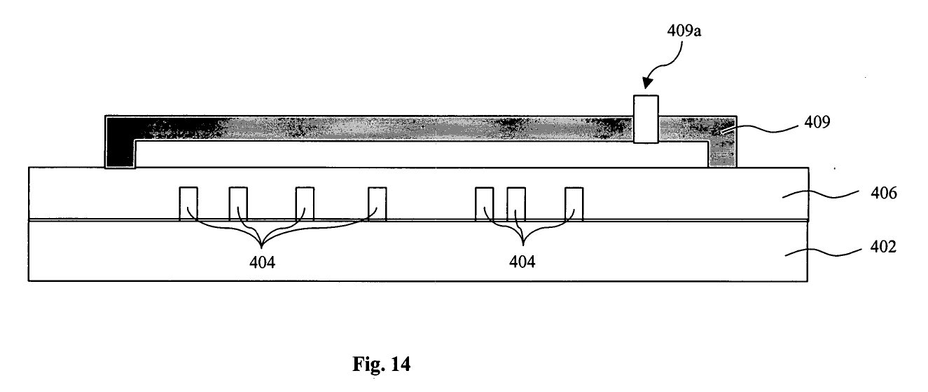

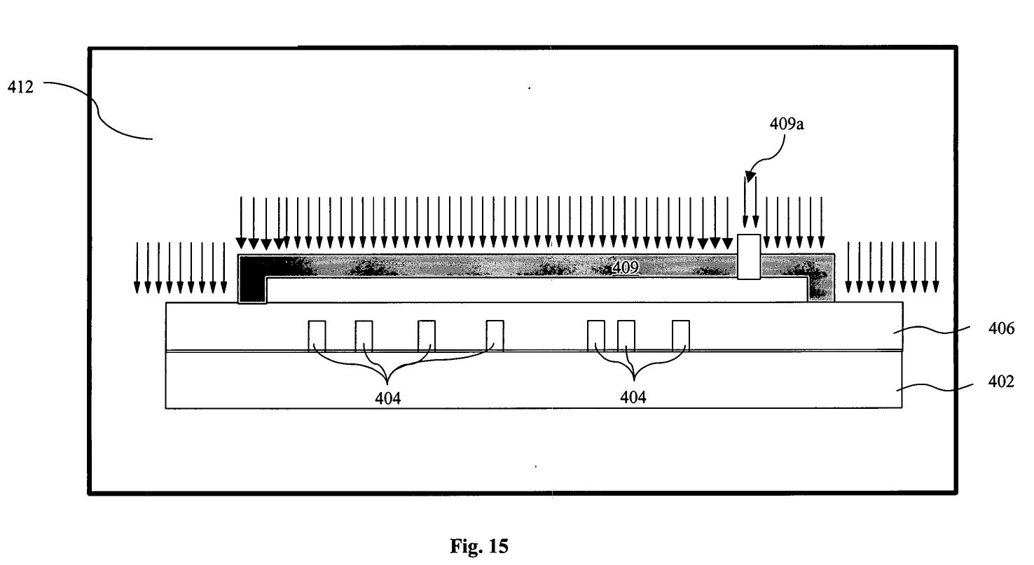

The protective cover 408 may comprise quartz, metal such as aluminum and stainless steel, and/or polymer such as polyimide. The protective cover may have a wall thickness to be self-sustained. The protective cover may include a rim and a top portion. The rim may be in contact with the WRM layer. The top portion may be designed and configured to have no contact with the WRM layer and the absorption features at any point. The protective cover may be held to the photomask by a method such as vacuum technique as illustrated in FIG. 14, wherein the protective cover 409 may further include a valve 409a for vacuuming and releasing. The protective cover may be alternatively held by a pressure produced by weights or others.

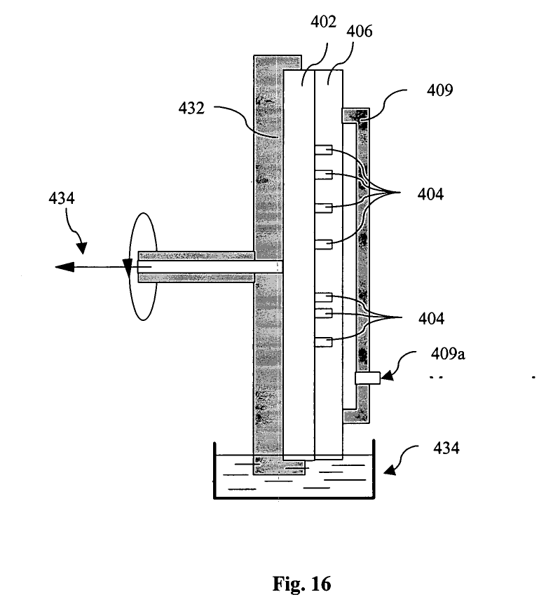

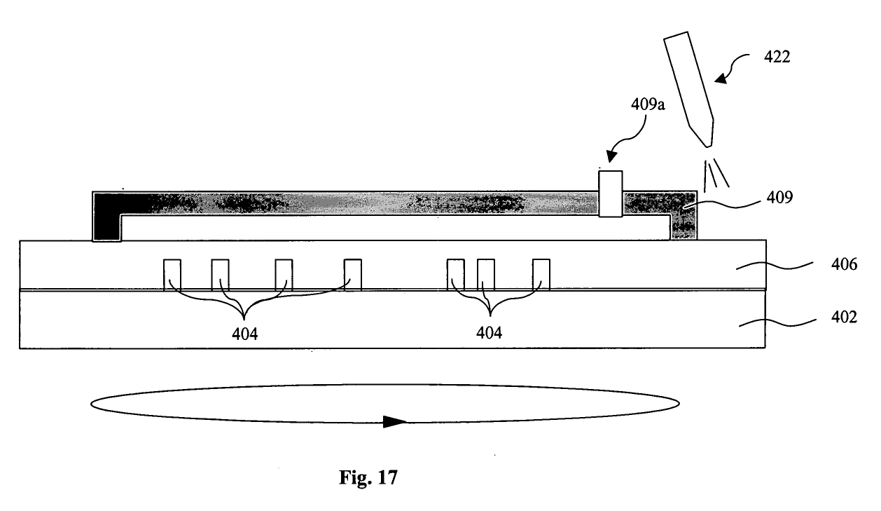

FIGS. 13a and 13b illustrate a top view and a cross-sectional view, respectively, of the photomask during another manufacturing stage. The edges of the WRM layer are removed when the absorption features and the rest of the WRM layer are protected by the protective layer. The removal of the edges of the WRM layer may be implemented by a dry etching as shown in FIG. 15, wherein the photomask along with the protective cover 409 are positioned inside a dry etching chamber 412. The removal of the edges of the WRM layer may be implemented by a wet etching as shown in FIG. 16, wherein the photomask along with the protective cover 409 may be held by a stage 432 and be partially dipped into an etching solution tank 434. The stage 432 and the photomask may rotate along an axis 436 normal to the surface of the photomask such that each portion of the edges of the WRM layer can be dipped in the etching solution long enough for removal. The removal of the edges of the WRM layer may be implemented using a liquid nozzle 422 as shown in FIG. 17, wherein the liquid nozzle 422 may project etching solution at edges of the WRM layer and the photomask may rotate such that the edges of the WRM layer are removed. The protective cover 409 is then taken off from the photomask and may be saved further use. The pellicle is attached to edges of the transparent substrate thereafter.

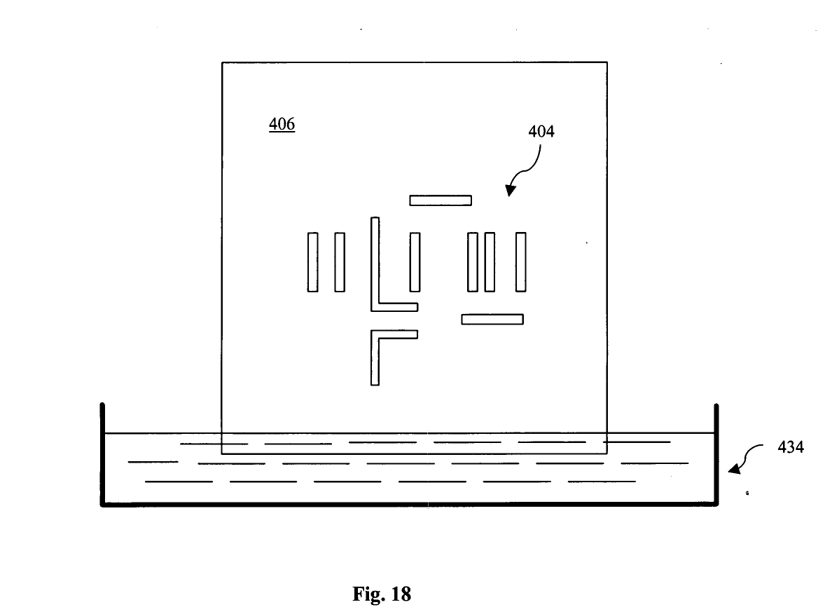

The edges of the WRM layer may be removed without using the protective cover. For example, the photomask may be held vertical and have its edge dipped in an etching solution tank 434 such that only the edge of the WRM layer is removed, as shown in FIG. 18. Then the photomask can be turned so that another edge is dipped in the etching solution tank until all edges of the WRM are properly removed.

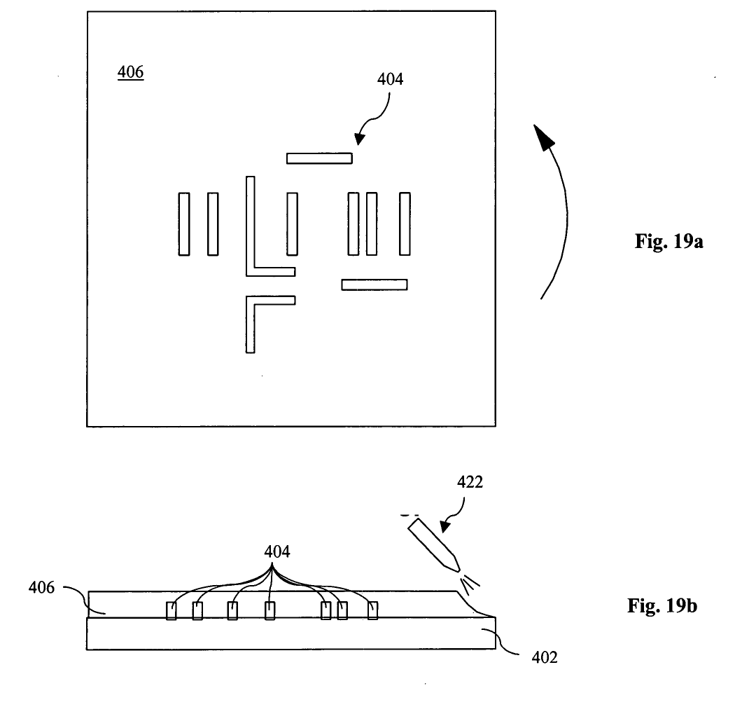

In another example as illustrated in FIGS. 19a and 19b, a liquid nozzle 422 is employed to project the etching solution at edges of the WRM layer. The photomask may be rotated such that all edges of the WRM layer are properly removed.

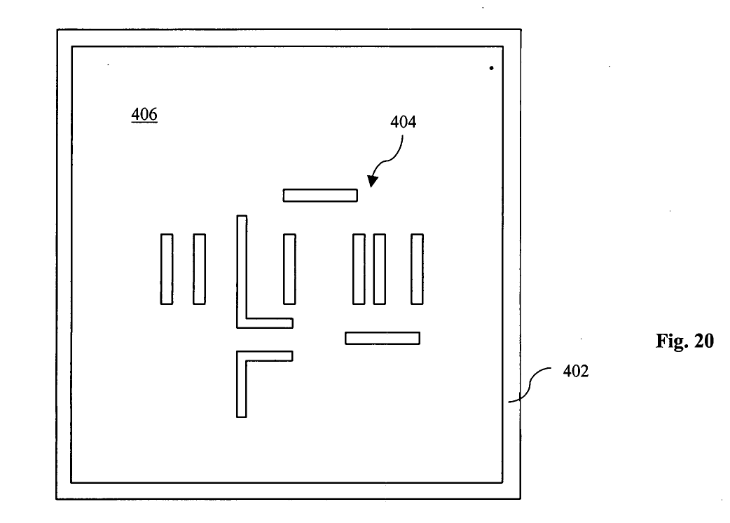

In a another example as illustrated in FIG. 20, the edges of the WRM layer may be removed by a lithography process. In the lithography process, the photomask may be coated with a layer of photoresist. The layer of photoresist is then exposed and developed such that edges of the photoresist layer are removed to expose the edges of the WRM layer. The exposed edges of the WRM layer can be removed by a method such as wet etching and dry etching. The layer of photoresist is removed thereafter either by a plasma ashing or wet stripping. Alternatively, if the WRM layer itself comprises photoresist, then forming the WRM layer and removing the edges thereof may be combined such that the edges of the WRM layer can be removed by a simplified lithography process without utilizing further photoresist coating, etching, and stripping processes. For instance, after its formation, the WRM layer can be exposed and developed so that the edges of the WRM layer are removed. During the above lithography process, other processes such as soft baking, hard baking, and post exposure baking may be incorporated properly, which is well know in the art.

Thus the present disclosure provides a photomask comprising a transparent substrate and an absorption layer proximate to the transparent substrate. The absorption layer has at least one opening formed therein. The photomask also comprises a wavelength-reducing material (WRM) layer disposed in the at least one opening, wherein the wavelength-reducing material and the absorption layer form a generally planar surface, and a pellicle mounted proximate to the transparent substrate. The pellicle may comprise a frame proximate to the transparent substrate and a film to cover the transparent substrate. The frame may be attached on the WRM layer at edges and the film substantially covers the absorption layer and the WRM layer. The frame may be attached on a patterned side of the transparent substrate at edges such that the film covers the absorption layer and the WRM layer. The frame may be attached onto a non-patterned side of the transparent substrate. The WRM layer may comprise a transparent polymer material, a photoresist material, or a transparent dielectric material. The WRM layer may have a refractive index different from that of the absorption layer.

The present disclosure also provides a method for fabricating a photomask comprising forming an absorption layer proximate to a transparent substrate, patterning the absorption layer, forming at least one opening in the absorption layer, forming a wavelength-reducing material (WRM) layer in the at least one opening of the absorption layer, and mounting a pellicle proximate to the transparent substrate. The mounting a pellicle may comprise attaching a frame of the pellicle on the WRM layer, substantially covers the absorption layer and the WRM layer. The mounting a pellicle may comprise attaching a frame of the pellicle on a non-patterned side of the transparent substrate. The mounting a pellicle may comprise mounting a frame of the pellicle on a patterned side of the transparent substrate such that the pellicle covers the absorption layer and the WRM layer. The mounting a pellicle may comprise: removing edges of the WRM layer to expose edges of the transparent substrate on the patterned side; and attaching the pellicle by gluing the frame of the pellicle on the edges of the transparent substrate. The method may further comprise: covering the WRM layer and the absorption layer using a protective cover, leaving edges of the WRM layer exposed before the removing edges; and taking away the protective cover after the removing edges. The protective cover may comprise a material selected from the group consisting of metal, quartz, and polymer. The protective cover may have a wall thickness to be self-sustained. The protective cover may include a rim and a top portion. The protective cover may include a valve for vacuuming and releasing. The WRM layer may be covered by the protective layer leaving a space between the WRM layer and a top of the protective layer. The WRM layer may be covered by holding the protective cover by vacuum and/or pressure. The edges of the WRM layer may be removed by methods such as dry etching, wet etching, liquid nozzle etching, and/or a lithography process. The pellicle may mounted comprise using glue for adhesion.

The present disclosure also provides a photolithography method comprising positioning a photomask above a semiconductor formation and exposing the photomask and semiconductor formation to light. The photomask includes a transparent substrate, an absorption layer proximate to the transparent substrate and defining at least one opening therein, a high refractive index layer disposed in the at least one opening of the absorption layer and operable to reduce a wavelength of light passing therethrough during photolithography, and a pellicle attached on the transparent substrate.

The present disclosure has been described relative to a preferred embodiment. Improvements or modifications that become apparent to persons of ordinary skill in the art only after reading this disclosure are deemed within the spirit and scope of the application. It is understood that several modifications, changes and substitutions are intended in the foregoing disclosure and in some instances some features of the invention will be employed without a corresponding use of other features. For example, one or more of the illustrated ARC layers may be excluded or additional ARC layers may be used. Materials used for the transparent substrate, absorption layer, wavelength reducing material, and ARC layers may vary, as may the method by which the various layers are formed. Accordingly, it is appropriate that the appended claims be construed broadly and in a manner consistent with the scope of the invention.

What is claimed is:

1. A photomask comprising:
a transparent substrate;
an absorption layer proximate to the transparent substrate, wherein the absorption layer has at least one opening formed therein;
a wavelength-reducing material (WRM) layer disposed in the at least one opening, wherein the wavelength-reducing material and the absorption layer form a generally planar surface; and
a pellicle mounted proximate to the transparent substrate.

2. The mask of claim 1 wherein the pellicle comprises a frame proximate to the transparent substrate and a film to cover the transparent substrate.

3. The mask of claim 2 wherein the frame is attached on the WRM layer at edges and the film substantially covers the absorption layer and the WRM layer.

4. The mask of claim 2 wherein the frame is attached on a patterned side of the transparent substrate at edges such that the film covers the absorption layer and the WRM layer.

5. The mask of claim 2 wherein the frame is attached onto a non-patterned side of the transparent substrate.

6. The photomask of claim 1 wherein the WRM layer comprises a material selected from the group consisting of a transparent polymer material, a photoresist material, and a transparent dielectric material.

7. The photomask of claim 1 wherein the WRM layer has a refractive index different from that of the absorption layer.

8. A method for fabricating a photomask comprising:
forming an absorption layer proximate to a transparent substrate;
patterning the absorption layer and forming at least one opening in the absorption layer;
forming a wavelength-reducing material (WRM) layer in the at least one opening of the absorption layer; and
mounting a pellicle proximate to the transparent substrate.

9. The method of claim 8 wherein the mounting a pellicle comprises attaching a frame of the pellicle on the WRM layer, substantially covers the absorption layer and the WRM layer.

10. The method of claim 8 wherein the mounting a pellicle comprises attaching a frame of the pellicle on a non-patterned side of the transparent substrate.

11. The method of claim 8 wherein the mounting a pellicle comprises mounting a frame of the pellicle on a patterned side of the transparent substrate such that the pellicle covers the absorption layer and the WRM layer.

12. The method of claim 11 wherein the mounting a pellicle comprises:
removing edges of the WRM layer to expose edges of the transparent substrate on the patterned side; and
attaching the pellicle by gluing the frame of the pellicle on the edges of the transparent substrate.

13. The method of claim 12 further comprising:
covering the WRM layer and the absorption layer using a protective cover, leaving edges of the WRM layer exposed before the removing edges; and
taking away the protective cover after the removing edges.

14. The method of claim 13 wherein the protective-cover comprises a material selected from the group consisting of metal, quartz, and polymer.

15. The method of claim 13 wherein the protective cover comprises a wall thickness to be self-sustained.

16. The method of claim 13 wherein the protective cover comprises a rim and a top portion.

17. The method of claim 13 wherein the protective cover comprises a valve for vacuuming and releasing.

18. The method of claim 13 wherein the covering the WRM layer comprises covering the WRM layer by the protective layer leaving a space between the WRM layer and a top of the protective layer.

19. The method of claim 13 wherein the covering the WRM layer comprises holding the protective cover by a method selected from the group consisting of vacuum and pressure.

20. The method of claim 13 wherein the removing edges of the WRM layer comprises utilizing a method selected from the group consisting of a dry etching, wet etching, and liquid nozzle etching.

21. The method of claim 12 wherein the removing edges of the WRM layer comprises utilizing a method selected from the group consisting of wet etching and liquid nozzle etching.

22. The method of claim 12 wherein the removing edges of the WRM layer comprises removing edges of the WRM layer by a lithography process.

23. A photolithography method comprising:
positioning a photomask above a semiconductor formation, the photomask comprising:
a transparent substrate;
an absorption layer proximate to the transparent substrate and defining at least one opening therein;
a high refractive index layer disposed in the at least one opening of the absorption layer and operable to reduce a wavelength of light passing therethrough during photolithography; and
a pellicle attached on the transparent substrate; and exposing the photomask and semiconductor formation to light.
